(19) United States
(12) Patent Application Publication
(10) Pub. No.: US 2026/0245646 A1
(43) Pub. Date: Aug. 20, 2026

(54) STORAGE DEVICE AND METHOD OF OPERATING STORAGE DEVICE

(71) Applicant: SAMSUNG ELECTRONICS CO., LTD., Suwon-si (KR)

(72) Inventors: Bong-Kil JUNG, Suwon-si (KR); Byongmo MOON, Suwon-si (KR); YOUNGDON CHOI, Suwon-si (KR); SEONGHYEOG CHOI, Suwon-si (KR)

(73) Assignee: SAMSUNG ELECTRONICS CO., LTD., Suwon-si (KR)

(21) Appl. No.: 19/444,943

(22) Filed: Jan. 9, 2026

(30) Foreign Application Priority Data
Jan. 20, 2025 (KR) 10-2025-0008019

(51) Int. Cl. G11C 29/36; G11C 29/12; G11C 29/20

(52) U.S. Cl. CPC G11C 29/36; G11C 29/12015; G11C 29/20; G11C 2029/3602

(57) ABSTRACT

A storage device includes a memory device that includes memory cells, and a memory controller that controls the memory device. The memory device includes a memory cell array that includes the memory cells, a control logic circuit that writes or senses data in or from the memory cell array in response to a command received from the memory controller, and a page buffer circuit that temporarily stores sensing data sensed from the memory cells. The memory controller may include a training module that generates first pattern data based on a seed, and the control logic circuit may include a pattern data check circuit that generates second pattern data based on a first training command and the seed, and compares the first pattern data and the second pattern data.

### CROSS-REFERENCE TO RELATED APPLICATION

This application claims priority under 35 U.S.C. § 119 to Korean Patent Application No. 10-2025-0008019 filed on Jan. 20, 2025, in the Korean Intellectual Property Office, the disclosure of which being incorporated by reference herein in its entirety.

### BACKGROUND

Embodiments of the present disclosure described herein relate to a storage device and an operating method of the storage device, and more particularly, relate to a storage device including a memory device outputting a result of comparing pattern data received from a memory controller and pattern data generated in the memory device, during a training operation and an operating method of the storage device.

Data are increasing with the development of artificial intelligence (AI) technologies. This increase may cause the increase in a storage capacity of a data center. The use of a storage device which is based on a semiconductor device is increasing in the data center and the cloud computing environment.

As the use of the storage device increases, a technology for improving the performance of the storage device is being researched and developed. In order to improve performance of the storage device, a data training operation may be used. The data training operation may take time.

### SUMMARY

It is an aspect to improve the performance of data training of a storage device.

It is another aspect to provide a storage device in which a memory device compares received pattern data with generated pattern data in the memory device without outputting sensed pattern data and outputs a comparison result and an operating method of the storage device.

According to an aspect of one or more embodiments, there is provided a storage device comprising a memory device including a plurality of nonvolatile memory cells; and a memory controller configured to control the memory device. The memory device includes a memory cell array including the plurality of nonvolatile memory cells; a control logic circuit configured to write or sense data in or from the memory cell array in response to a command received from the memory controller; and a page buffer circuit configured to temporarily store sensing data sensed from the plurality of nonvolatile memory cells. The memory controller includes a training module configured to generate first pattern data based on a seed, and the control logic circuit includes a pattern data check circuit configured to generate second pattern data based on a first training command and the seed; and compare the first pattern data and the second pattern data.

According to another aspect of one or more embodiments, there is provided a memory device comprising a memory cell array including a plurality of nonvolatile memory cells; a page buffer circuit configured to temporarily store sensing data sensed from the plurality of nonvolatile memory cells; and a control logic circuit configured to write or sense data in or from the plurality of nonvolatile memory cells in response to a command received from an external device that is external to the memory device. The control logic circuit is configured to store each of a plurality of first pattern data in the page buffer circuit in response to a training command received from the external device; generate a plurality of second pattern data based on a seed; and output a result of comparing each of the plurality of first pattern data with a respective one of the plurality of second pattern data.

According to yet another aspect of one or more embodiments, there is provided a method of a storage device, the method comprising receiving, at a memory device, a first training command and first pattern data from a memory controller; generating, at the memory device, second pattern data based on a seed, in response to the first training command; generating, at the memory device, a first comparison result of comparing the first pattern data and the second pattern data; and outputting, at the memory device, comparison data based on the first comparison result.

### BRIEF DESCRIPTION OF THE FIGURES

The above and other aspects will become apparent by describing in detail embodiments thereof with reference to the accompanying drawings.

FIG. 1 is a block diagram illustrating a storage device according to an embodiment.

FIG. 2 is a block diagram illustrating an example of a configuration of a memory controller of FIG. 1, according to an embodiment.

FIGS. 3 and 4 are diagrams illustrating operations during data training, according to embodiments.

FIG. 5 is a block diagram illustrating an example of a configuration of a pattern data check circuit of a memory device, according to an embodiment.

FIG. 6 is a diagram illustrating a configuration of a nonvolatile memory device of a storage device according to an embodiment.

FIG. 7 is a diagram illustrating a memory block of a three-dimensional V-NAND structure applicable to a storage device according to an embodiment.

FIG. 8 is a block diagram illustrating an example of a configuration of a memory device, according to an embodiment.

FIG. 9 is a flowchart describing an operation of a storage device according to an embodiment.

FIG. 10 is a diagram describing an operation of a storage device of FIG. 9, according to an embodiment.

FIG. 11 is a flowchart describing an operation of a storage device according to an embodiment.

FIG. 12 is a diagram describing an operation of a storage device of FIG. 11, according to an embodiment.

FIG. 13 is a flowchart describing an operation of a storage device according to an embodiment.

FIG. 14 is a diagram describing an operation of a storage device of FIG. 13, according to an embodiment.

FIG. 15 is a block diagram illustrating an example of a configuration of a memory card system according to an embodiment.

### DETAILED DESCRIPTION

As discussed above, as the use of the storage device increases, a technology for improving the performance of the storage device is being researched and developed. During a data training operation, a memory device of a conventional storage device receives pattern data from a memory controller and again outputs the pattern data to the memory controller. The memory controller compares the pattern data received from the memory device with pattern data before programming. The exchange of the pattern data between the memory controller and the memory device during the data training operation increases the time taken to perform data training.

According to various embodiments, a storage device may perform a data training operation in which a memory device may not output pattern data, but the memory device may compare the received pattern data with pattern data that has been generated internally in the memory device 120, and may output a comparison result to a memory controller of the storage device.

Below, various embodiments of the present disclosure will be described in detail and clearly to such an extent that an ordinary one in the art may easily carry out the various embodiments of the present disclosure. As used in this specification, a phrase using the form “at least one of A, B, or C” includes within its scope “only A”, “only B”, “only C”, “A and B”, “A and C”, “B and C” and “A, B, and C.”

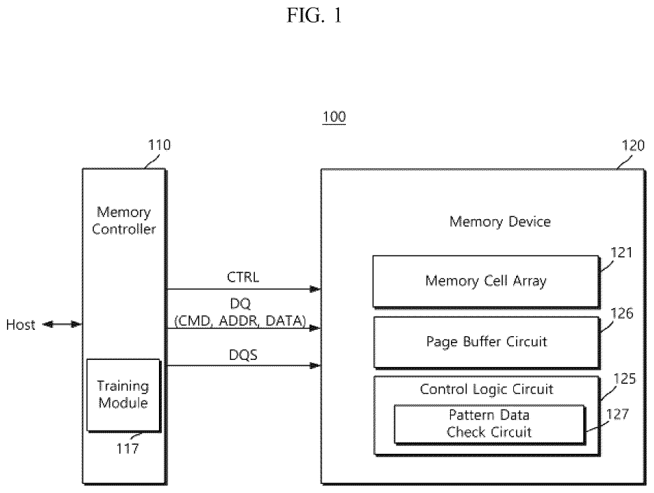

FIG. 1 is a block diagram illustrating a storage device 100 according to an embodiment.

Referring to FIG. 1, the storage device 100 may include a memory controller 110 and a memory device 120. In an embodiment, the memory device 120 may be a nonvolatile memory device.

In the storage device 100 according to an embodiment, during a data training operation, the memory device 120 may not output pattern data. The memory device 120 may compare the received pattern data with the pattern data that has been generated internally in the memory device 120. The memory device 120 may output a comparison result. The output comparison result may be transmitted to the memory controller 110. The memory controller 110 may adjust a parameter associated with at least one of a data strobe signal or a data signal based on the comparison result.

The storage device 100 according to an embodiment will be described in detail with reference to FIG. 1.

The memory controller 110 may control the memory device 120 to perform an input/output request of a host. The memory controller 110 may be configured to control the memory device 120 under control of the host or depending on a command from the host. The input/output request may include a program, read, and/or erase request for user data, which the host requests from the storage device 100. For example, depending on the request of the host, the memory controller 110 may write data in the memory device 120 or may read data that is stored in the memory device 120 from the memory device 120. To control the memory device 120, the memory controller 110 may provide the memory device 120 with a control signal CTRL, a data signal DQ, and a data strobe signal DQS. The data signal DQ may include a command CMD, an address ADDR, and data “DATA”.

The memory device 120 may store data received from the memory controller 110 or may transmit the stored data to the memory controller 110. The memory device 120 may be provided as a storage medium of the storage device 100.

The memory device 120 may include a plurality of nonvolatile memory devices. For example, the memory device 120 may include a plurality of flash memory devices. The memory device 120 may include a flash memory device of a two-dimensional (2D) structure or a three-dimensional (3D) structure. The flash memory device may be implemented with nonvolatile memory devices such as a NAND flash memory, a vertical NAND (V-NAND) flash memory, a NOR flash memory, a magnetic memory (MRAM), a phase-change memory (PRAM), a ferroelectric random access memory (FRAM), a spin transfer torque random access memory (STT-RAM), and/or a resistive RAM (RRAM).

In general, the plurality of flash memory devices are connected to the memory controller 110 in units of channel. A plurality of flash memory devices which communicate through the same data bus are connected to one channel. The memory device 120 may communicate with the memory controller 110 in a channel/way interleaving manner.

In an embodiment, the storage device 100 may include a buffer memory device. The buffer memory device may be used as a data buffer for data exchange between the storage device 100 and the host. Write data provided from the host or data read from the memory device 120 are temporarily stored in the buffer memory device. When data read-requested by the host and present in the memory device 120 are cached in the buffer memory device, the buffer memory device may support a cache function of providing the cached data directly to the host.

The memory device 120 may include a memory cell array 121, a control logic circuit 125, and a page buffer circuit 126. In an embodiment, the control logic circuit 125 may include a pattern data check circuit 127.

The memory cell array 121 may include a plurality of memory blocks, and each of the plurality of memory blocks may include a plurality of memory cells.

The control logic circuit 125 may overall control various kinds of operations of the memory device 120. For example, in response to a command received from the memory controller 110, the control logic circuit 125 may program data in memory cells of the memory cell array 121 or may sense data from the memory cells. According to an embodiment, the memory device 120 may transmit or may not transmit the sensed data to the memory controller 110.

In a read operation of the memory device 120, the page buffer circuit 126 may read data stored in a memory cell by sensing a current or a voltage of a selected bit line. The page buffer circuit 126 may temporarily store data sensed from memory cells.

The control logic circuit 125 may store first pattern data received from the memory controller 110 in the page buffer circuit 126 in response to a training command received from the memory controller 110.

In an embodiment, the control logic circuit 125 may store the first pattern data in the page buffer circuit 126 in response to a first command for write data signal (DQ) training from the memory controller 110.

The page buffer circuit 126 may store the first pattern data. For example, a first latch circuit of the page buffer circuit 126 may store the first pattern data.

The pattern data check circuit 127 of the control logic circuit 125 may generate second pattern data based on a seed. The second pattern data may be stored in a second latch circuit of the page buffer circuit 126.

The pattern data check circuit 127 may compare the first pattern data of the first latch circuit with the second pattern data of the second latch circuit. That is, the pattern data check circuit 127 may compare the received first pattern data stored in the first latch circuit with the second pattern data that has been generated in the memory device 120 and stored in the second latch circuit. The control logic circuit 125 may output a comparison result. The output comparison result may be transmitted to the memory controller 110. According to the above description, the memory device 120 may output the comparison result, which is obtained through a compare operation of a page buffer circuit without reading and writing pattern data from and in a memory cell array, and thus, a time taken for the storage device 100 to perform the training operation may decrease.

The memory controller 110 may receive the comparison result of the pattern data transmitted by the memory controller 110 and the pattern data generated in the memory device 120.

In an embodiment, the memory controller 110 may adjust a parameter associated with at least one of the data strobe signal DQS or the data signal DQ based on the comparison result.

In an embodiment, the memory controller 110 may adjust the timing of the data strobe signal DQS based on the comparison result. For example, the memory controller 110 may delay the data strobe signal DQS as much as a step. The step may be preset. In this case, the memory controller 110 may include delay circuits.

In an embodiment, the memory controller 110 may align the data strobe signal DQS to the data signal DQ, based on the comparison result. For example, the memory controller 110 may align the rising edge or falling edge of the data strobe signal DQS to a center of the data signal DQ. In this case, the memory controller 110 may include delay circuits.

The embodiment illustrated in FIG. 1 describes the write data signal (DQ) training as an example, but embodiments are not limited to the write data signal (DQ) training. In the specification, the write data signal (DQ) training is described as an example, but the storage device 100 according to an embodiment may perform at least one of a ZQ calibration operation, a duty cycle corrector (DCC) training operation, a read training operation, or a write training operation. During the execution of the at least one of the ZQ calibration operation, the duty cycle corrector (DCC) training operation, the read training operation, or the write training operation, the storage device 100 may perform the compare operation of pattern data received by the memory device 120 and pattern data generated internally by the memory device 120. In an embodiment, the memory device 120 may transmit the comparison result without transmitting the pattern data to the memory controller 110.

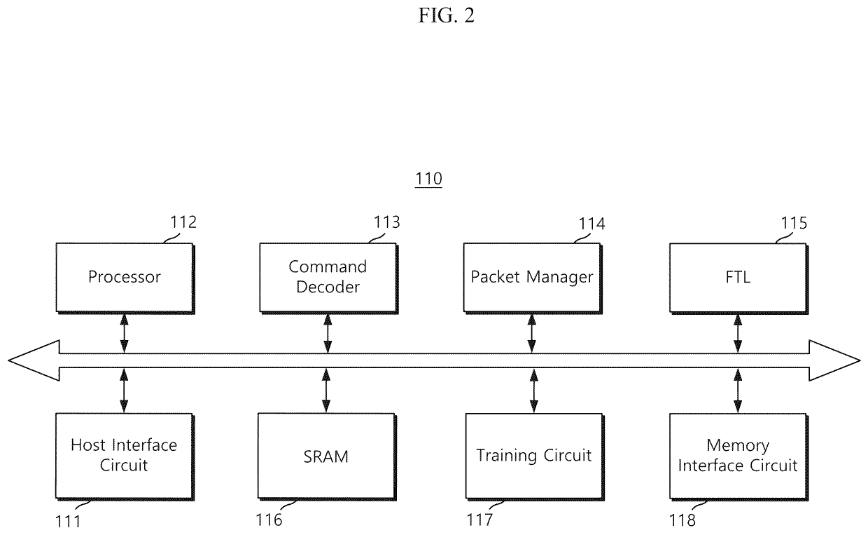

FIG. 2 is a block diagram illustrating an example of a configuration of the memory controller 110 of FIG. 1, according to an embodiment.

The memory controller 110 may include a host interface circuit 111, a processor 112, a command decoder 113, a packet manager 114, a flash translation layer (FTL) 115, an SRAM 116, a training circuit 117, and a memory interface circuit 118.

The memory controller 110 may communicate with the host through the host interface circuit 111. The host interface circuit 111 may be implemented with various interface manners such as advanced technology attachment (ATA), serial ATA (SATA), external SATA (e-SATA), small computer small interface (SCSI), serial attached SCSI (SAS), peripheral component interconnection (PCI), PCI express (PCIe), IEEE 1394, universal serial bus (USB), NVMe, and/or CXL.

The processor 112 may be implemented with a circuit, logic, a code, or a combination thereof. The processor 112 controls all operations of the storage device 100 including the memory controller 110. When the storage device 100 is driven, the processor 112 may load firmware stored in a read only memory (ROM) to a memory device and may perform all operations of the memory controller 110. The processor 112 may load the flash translation layer (FTL) 115 to a working memory. Based on an address translation result of the flash translation layer (FTL) 115, the processor 112 may program data in the memory device 120 and/or may read data from the memory device 120.

The command decoder 113 may decode a command parsed from a packet, based on the protocol agreed upon between the host and the interface. The packet manager 114 may parse the command from the packet received from the host, based on the protocol agreed upon between the host and the interface. For example, the command decoder 113 may decode an opcode of a command which is based on a specific protocol and may identify a program command, an erase command, a read command, and/or a secure erase command. The processor 112 may perform the request of the host depending on the decoded commands. In an embodiment, the command decoder 113 may be implemented as an independent circuit and/or part of firmware.

The flash translation layer (FTL) 115 may perform various functions (or operations) such as address mapping, wear-leveling, and/or garbage collection. For example, in some embodiments, the flash translation layer (FTL) 115 may perform, under control of the processor 112, various functions (or operations) such as address mapping, wear-leveling, and/or garbage collection. For example, in some embodiments, the processor 112 may execute the flash translation layer (FTL) 115 to perform the various functions (or operations) such as the address mapping, the wear-leveling, and/or the garbage collection.

The address mapping operation refers to an operation of translating a logical address received from the host into a physical address to be actually used to program data in the memory device 120. In an embodiment, the logical address may be a logical block address (LBA) and/or a logical page number (LPN).

For example, a logical block address of user data which are requested by the host to be programmed may be translated into a physical address of the memory device 120 of FIG. 1 by using the flash translation layer (FTL) 115. In an embodiment, the physical address may be a physical page number (PPN). In an embodiment, an address mapping table which the flash translation layer (FTL) 115 manages may store information about a mapping relationship between a logic page number (LPN) and a physical page number. In an embodiment, each of logic page numbers LPN may correspond to a plurality of logical block addresses (LBA).

In an embodiment, the flash translation layer (FTL) 115 may include information about a kind of the memory cells of the memory cell array 121 of FIG. 1. For example, the flash translation layer (FTL) 115 may include information indicating that memory cells in a first zone are implemented with single level cells and memory cells in a second zone are implemented with any other cells (e.g., multi-level cells or triple level cells) other than the single level cells.

The wear-leveling may be a technology which allows memory blocks of the memory device 120 of FIG. 1 to be used uniformly such that excessive degradation of a specific memory block is prevented. The wear-leveling may be implemented through a firmware technology for balancing erase counts of physical blocks, for example.

The garbage collection may be used to secure an available capacity of the memory device 120 of FIG. 1 through a way to copy valid data of an existing memory block to a new memory block and to then erase the existing memory block.

The SRAM 116 may store temporary data, temporary variables, etc. for performing the operation of the processor 112.

The training circuit 117 according to an embodiment may transmit a first training command to the memory device 120. In some embodiments, the training circuit 117 may be implemented by program code which is executed by the processor 112 in order to implement the operations discussed herein.

In an embodiment, the first training command may include a logical address and an operation code for performing write training of a transmission side. For example, in an embodiment, the operation code may be “63h”. The training circuit 117 may transmit pattern data after the logical address. The training circuit 117 may check the size of the pattern data by using a get feature operation. The training circuit 117 may output the pattern data based on the checked size.

In an embodiment, the first training command may include a new operation code for performing the write training of the transmission side. The first training command may not include a logical address. The training circuit 117 may transmit pattern data after the operation code.

In an embodiment, the training circuit 117 may transmit a seed, which is used to generate second pattern data, to the memory device 120 by using a set feature operation before the transmission of the first training command. For example, the seed may be a seed which is used for the memory controller 110 to generate the first pattern data.

The training circuit 117 may generate the first pattern data by using the seed. In an embodiment, the training circuit 117 may include a linear feedback shift register (LFSR) which receives the seed and outputs the first pattern data. In an embodiment, the training circuit 117 may include a lookup table retrieving circuit which outputs the first pattern data corresponding to the seed based on a lookup table.

The training circuit 117 may transmit a second training command after transmitting the pattern data together with the first training command. For example, the second training command may include an address and an operation code for performing a response of the write training of the transmission side. In an embodiment, the operation code may be “64h”. In some embodiments, the second training command may include a new operation code for performing a response of the write training of the transmission side. In this case, the second training command may not include an address after the new operation code.

After the training circuit 117 transmits the second training command, the training circuit 117 may receive a comparison result from the memory device 120 based on the data strobe signal DQS. For example, as a response to the second training command, the training circuit 117 may receive, from the memory device 120, a comparison result of comparing the pattern data transmitted to the memory device 120 with the pattern data generated by the memory device 120.

The training circuit 117 may terminate the data signal (DQ) training operation, based on the comparison result. In some embodiments, based on the comparison result, the training circuit 117 may adjust a parameter associated with at least one of the data strobe signal DQS or the data signal DQ, and may again perform the data signal (DQ) training operation.

The training circuit 117 according to an embodiment may not receive the pattern data from the memory device 120, as a response to the second training command. That is, the training circuit 117 may receive comparison result of comparing the transmitted pattern data with the pattern data generated internally in the memory device 120. Accordingly, the memory controller 110 may not compare the pattern data transmitted to the memory device 120 with the pattern data received from the memory device 120. The memory controller 110 may receive only the comparison result without receiving the sensed pattern data from the memory device 120, and thus, a time taken to perform the training operation may decrease.

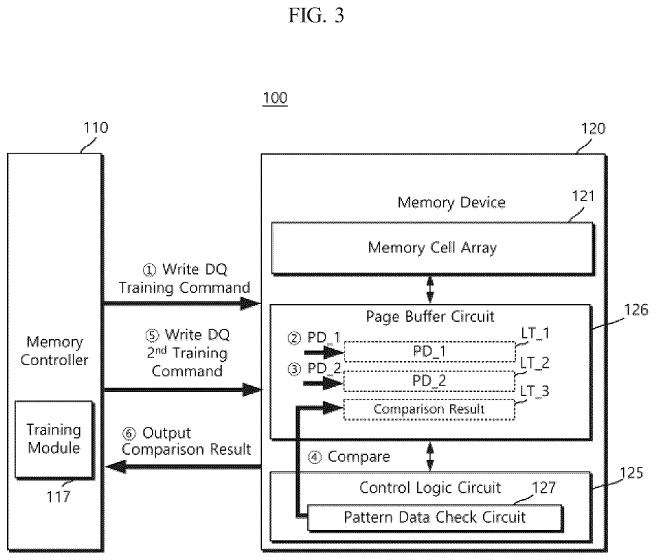

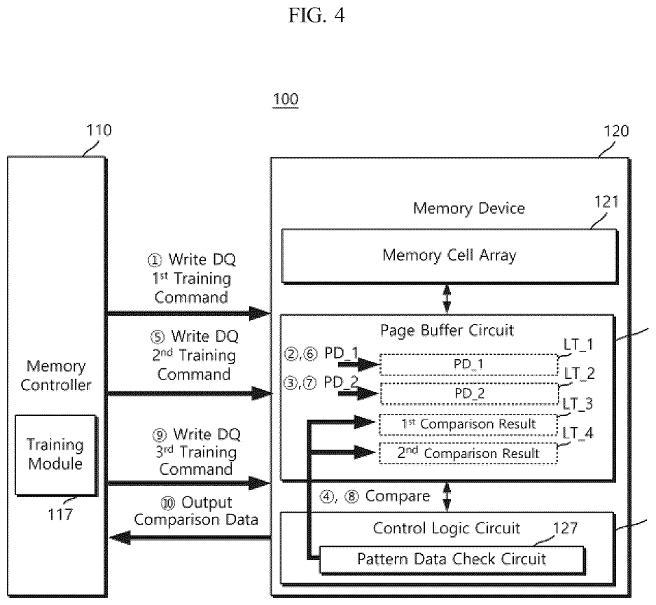

FIGS. 3 and 4 are diagrams illustrating operations during data training, according to embodiments. FIGS. 3 and 4 show operations of the storage device 100 of FIG. 1. Operations according to embodiments of the storage device 100 will be described with reference to FIGS. 3 and 4. The description which is the same as or similar to the description given with reference to FIGS. 1 and 2 will be omitted for conciseness.

An operation of the storage device 100, according to an embodiment will be described with reference to FIG. 3.

Referring to FIG. 3, the memory controller 110 may transmit a first training command for performing data signal (DQ) training (indicated by a circled 1 in FIG. 3). The memory controller 110 may transmit first pattern data PD_1 after the first training command. The memory device 120 may capture the first pattern data PD_1 based on the data strobe signal DQS or a data strobe bar signal DQS of the memory controller 110 (circled 2). For example, the memory device 120 may store the first pattern data PD_1 captured from the data signal DQ in a first latch circuit LT_1 of the page buffer circuit 126 based on the data strobe signal DQS or the data strobe bar signal D̅Q̅S̅. Accordingly, when the data strobe signal DQS and the data signal DQ are not aligned, a portion of the data signal DQ may not be accurately captured.

The pattern data check circuit 127 may generate second pattern data PD_2 based on a seed (circled 3). The pattern data check circuit 127 may store the second pattern data PD_2 in a second latch circuit LT_2 of the page buffer circuit 126.

The memory device 120 may compare the first pattern data PD_1 stored in the first latch circuit LT_1 with the second pattern data PD_2 stored in the second latch circuit LT_2 and may store a comparison result in a third latch circuit LT_3 (circled 4).

According to an embodiment, the third latch circuit LT_3 may be a latch circuit different from the first latch circuit LT_1 and the second latch circuit LT_2 or may be the same circuit as any one of the first latch circuit LT_1 and the second latch circuit LT_2.

For example, the pattern data check circuit 127 may compare each bit of the first pattern data PD_1 stored in the first latch circuit LT_1 with each bit of the second pattern data PD_2 stored in the second latch circuit LT_2 in order and may store a comparison result for each bit in order in the third latch circuit LT_3 which, as described above, may be a latch circuit different from LT_1 and LT2, or may be the same circuit as any one of the first latch circuit LT_1 and the second latch circuit LT_2.

In an embodiment, the memory device 120 may compare each bit of the first pattern data PD_1 with each bit of the second pattern data PD_2 and may store a comparison result for each bit. For example, the memory device 120 may store a result of performing an exclusive OR (XOR) operation on each bit of the first pattern data PD_1 and each bit of the second pattern data PD_2. For example, when the first pattern data PD_1 includes, for example, 10 bits, and the second pattern data PD_2 includes 10 bits, the pattern data check circuit 127 may compare the 10 bits of the first pattern data PD_1 with corresponding ones of the 10 bits of the second pattern data PD_2, such that, for example, bit 1 of PD_1 would be compared to bit 1 of PD_2, bit 2 of PD_1 would be compared with bit 2 of PD_2, and so on, and the comparison result would then include 10 bits of the results of the bit by bit comparison.

When the data strobe signal DQS and the data signal DQ do not coincide with each other, the first pattern data PD_1 and the second pattern data PD_2 respectively generated by the memory controller 110 and the memory device 120 based on the same seed may be different from each other. For example, at least one bit of the first pattern data PD_1 may be different in value from at least one bit of the second pattern data PD_2. Accordingly, the comparison result of the first pattern data PD_1 and the second pattern data PD_2 may include position information of a bit which does not coincide each other between bits of the first pattern data PD_1 and bits of the second pattern data PD_2.

After the memory controller 110 transmits the first training command and the first pattern data PD_1 to the memory device 120, the memory controller 110 may check a status register of the memory device 120.

For example, the memory controller 110 may send a status query command to the memory device 120. For example, the memory controller 110 may send a read status command to the memory device 120.

For example, the memory controller 110 may monitor a ready/busy signal R/B of the memory device 120. In an embodiment, after the ready/busy signal R/B transitions to a ready state, the memory controller 110 may transmit a second training command for requesting the comparison result to the memory device 120 (circled 5).

In response to the second training command, the memory device 120 may output the comparison result of comparing the first pattern data PD_1 with the second pattern data PD_2 (circled 6). The comparison result may be transmitted to the memory controller 110.

While an example is described above in which the memory device 120 outputs the comparison result, embodiments are not limited thereto. In some embodiments, the memory device 120 may output comparison data based on the comparison result. For example, the comparison data may include the comparison result. For example, the memory device 120 may provide comparison data indicating to the memory controller 110 that the first pattern data PD_1 did not match the second pattern data PD_2 without providing the bit by bit comparison result itself to the memory controller 110. In this case, the memory device 120 may transmit, for example, a flag or other indication to the memory controller 110 as the comparison data.

An operation of the storage device 100 according to an embodiment will be described with reference to FIG. 4. A difference between the embodiment described with reference to FIG. 3 and the embodiment to be described with reference to FIG. 4 will be mainly described for conciseness.

Referring to FIG. 4, the memory controller 110 may transmit a plurality of first pattern data PD_1. The memory device 120 may generate a plurality of second pattern data PD_2 corresponding to the plurality of first pattern data PD_1. The memory device 120 may generate a plurality of comparison results of comparing the plurality of first pattern data PD_1 with the plurality of second pattern data PD_2, respectively. The memory device 120 may simultaneously output the plurality of comparison results.

The description will be given in detail with reference to FIG. 4. The memory controller 110 may transmit the first training command and the (1-1)-th pattern data PD_1 (that is, the first pattern data PD_1 firstly received) to the memory device 120 (indicated by a circled 1 in FIG. 4). The memory device 120 may store the received (1-1)-th pattern data PD_1 in the first latch circuit LT_1 (circled 2) and may generate the (1-2)-th pattern data PD_2 (that is, the second pattern data PD_2 firstly generated). The memory device 120 may store the (1-2)-th pattern data PD_2 in the second latch circuit LT_2 (circled 3).

The memory device 120 may compare the (1-1)-th pattern data PD_1 with the (1-2)-th pattern data PD_2 (circled 4) and may store a first comparison result in the third latch circuit LT_3.

Before the memory controller 110 receives the first comparison result, the memory controller 110 may transmit the second training command and the (2-1)-th pattern data PD_1 to the memory device 120 (circled 5). The memory device 120 may store the received (2-1)-th pattern data PD_1 in the first latch circuit LT_1 (circled 6), may generate the (2-2)-th pattern data PD_2 based on a seed, and may store the (2-2)-th pattern data PD_2 in the second latch circuit LT_2 (circled 7).

The memory device 120 may compare the (2-1)-th pattern data PD_1 with the (2-2)-th pattern data PD_2 (circled 8) and may store a second comparison result in a fourth latch circuit LT_4.

The storage device 100 may transmit a third training command for requesting a comparison result to the memory device 120 (circled 9).

In response to the third training command, the memory device 120 may simultaneously output comparison data based on the first comparison result and the second comparison result (circled 10).

In an embodiment, the memory device 120 may continuously output the first comparison result and the second comparison result. The memory controller 110 may distinguish the first comparison result from the second comparison result based on a size of pattern data checked through the get feature operation. For example, each of the first comparison result and the second comparison result may be identical in size to the pattern data.

In an embodiment, as comparison data, the memory device 120 may output a result of performing an OR operation on the first comparison result and the second comparison result. The size of the comparison data may be identical to the size of the pattern data.

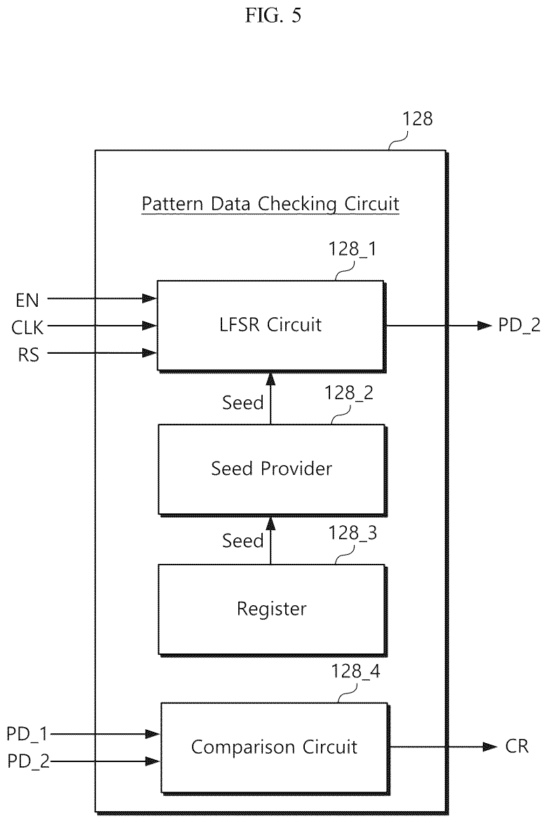

FIG. 5 is a block diagram illustrating an example of a configuration of the pattern data check circuit 127 of the memory device 120, according to an embodiment.

Referring to FIG. 5, the pattern data check circuit 127 may include a linear feedback shift register (LFSR) circuit 128_1, a seed provider 128_2, a register 128_3, and a comparison circuit 128_4.

The linear feedback shift register (LFSR) circuit 128_1 may be similar in configuration to the linear feedback shift register circuit of the memory controller 110. For example, the linear feedback shift register (LFSR) circuit 128_1 may be provided with a seed including bits, the number of which is the same as that of the linear feedback shift register circuit of the memory controller 110. The linear feedback shift register (LFSR) circuit 128_1 may include XOR gates at the same locations as registers, the number of which is the same as that of the linear feedback shift register circuit of the memory controller 110.

The linear feedback shift register (LFSR) circuit 128_1 may be provided with a seed from the seed provider 128_2. The seed provider 128_2 may retrieve a seed from the register 128_3. In an embodiment, the seed may be stored in the register 128_3 by the set feature operation of the memory controller 110.

In an embodiment, the comparison circuit 128_4 may include an XOR gate. The comparison circuit 128_4 may output a comparison result CR obtained by performing an XOR operation on each bit of the first pattern data PD_1 and each bit of the second pattern data PD_2.

In an embodiment, the comparison circuit 128_4 may include an OR gate. The comparison circuit 128_4 may output comparison data obtained by performing an OR operation on the first comparison result and the second comparison result.

According to an embodiment, the linear feedback shift register (LFSR) circuit 128_1, the seed provider 128_2, and the register 128_3 may be implemented with a circuit independent of the comparison circuit 128_4.

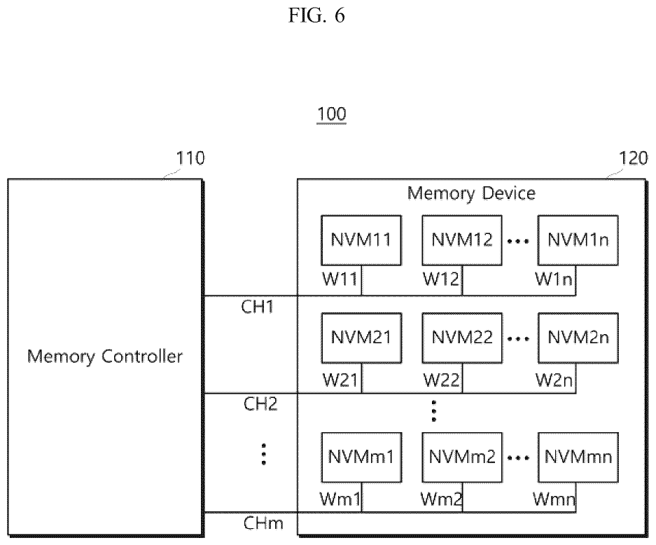

FIG. 6 is a diagram illustrating a configuration of the nonvolatile memory device 120 of the storage device 100 according to an embodiment. The storage device 100, the memory controller 110, and the memory device 120 of FIG. 6 may respectively correspond to the storage device 100, the memory controller 110, and the memory device 120 of FIG. 1.

The memory controller 110 may perform an I/O on a plurality of memory devices NVM11 to NVMmn through a plurality of channels CH1 to CHm. The memory device 120 and the memory controller 110 may be connected through the plurality of channels CH1 to CHm. In an embodiment, the memory controller 110 may include a plurality of controller modules respectively corresponding to the plurality of channels CH1 to CHm (i.e., may include a controller module for each channel).

The memory controller 110 may independently control memory devices (e.g., NVM11 to NVM1n) connected to one of the plurality of channels CH1 to CHm through ways.

The memory controller 110 may exchange signals with the memory device 120 through the plurality of channels CH1 to CHm.

The memory device 120 may include the plurality of nonvolatile memory devices NVM11 to NVMmn. Each of the nonvolatile memory devices NVM11 to NVMmn may be a nonvolatile memory package. In an embodiment, each of the nonvolatile memory devices NVM11 to NVMmn may include a plurality of dies, but embodiments are not limited thereto.

In an embodiment, the memory controller 110 according to an embodiment may train the plurality of memory devices NVM11 to NVMmn in parallel independently of each other.

In an embodiment, the controller module for each channel may train memory devices connected to the same channel in parallel. As described with reference to FIGS. 1 to 5, each of the plurality of memory devices NVM11 to NVMmn of the memory device 120 may output a comparison result of the received pattern data and the pattern data generated internally in the memory device 120 without outputting pattern data during the training operation. Accordingly, the communication of the memory controller 110 with each of the plurality of memory devices NVM11 to NVMmn may be reduced. Accordingly, the controller module for each channel may train memory devices connected to the same channel in parallel.

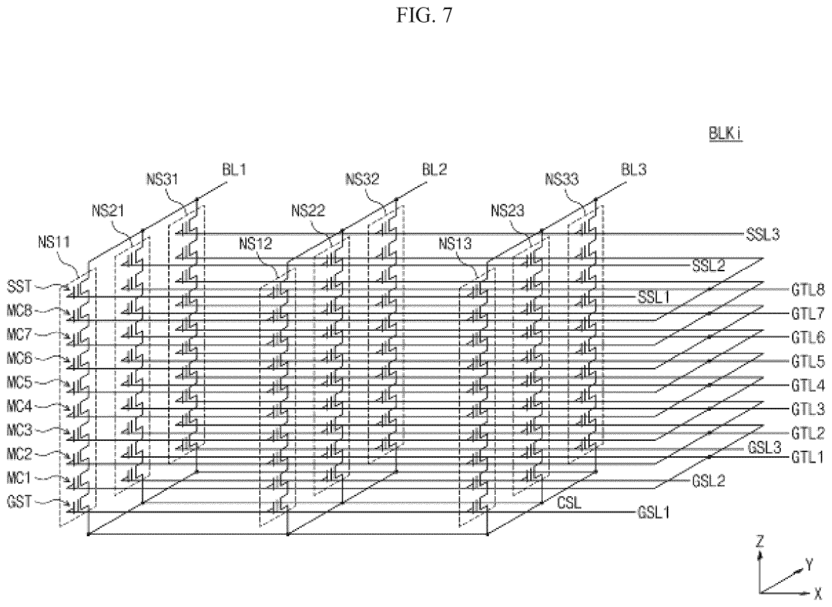

FIG. 7 is a diagram illustrating a configuration of a memory block according to an embodiment. A memory block BLKi of FIG. 7 may be one of memory blocks included in the memory cell array 121 of the memory device 120 of FIG. 1.

When the memory device 120 of the storage device 100 of FIG. 1 is implemented with a flash memory of a 3D V-NAND type, each of the plurality of memory blocks constituting the memory device 120 may be expressed by an equivalent circuit illustrated in FIG. 7.

The memory block BLKi illustrated in FIG. 7 indicates a three-dimensional memory block formed on a substrate in a three-dimensional structure. For example, a plurality of memory NAND strings included in the memory block BLKi may be formed in a direction perpendicular to the substrate.

Referring to FIG. 7, the memory block BLKi may include a plurality of memory NAND strings NS11 to NS33 connected between bit lines BL1, BL2, and BL3 and a common source line CSL. Each of the plurality of memory NAND strings NS11 to NS33 may include a string selection transistor SST, a plurality of memory cells MC1, MC2, . . . , MC8, and a ground selection transistor GST. An embodiment in which each of the plurality of memory NAND strings NS11 to NS33 includes eight memory cells MC1, MC2, . . . , MC8 is illustrated in FIG. 7, but an embodiment of the present disclosure is not necessarily limited thereto.

The string selection transistor SST may be connected to a corresponding one of string selection lines SSL1, SSL2, and SSL3. The plurality of memory cells MC1, MC2, . . . , MC8 may be respectively connected to gate lines GTL1, GTL2, . . . , GTL8. The gate lines GTL1, GTL2, . . . , GTL8 may correspond to word lines, and at least one of the gate lines GTL1, GTL2, . . . , GTL8 may correspond to a dummy word line. The ground selection transistor GST may be connected to a corresponding one of ground selection lines GSL1, GSL2, and GSL3. The string selection transistor SST may be connected to a corresponding bit line among the bit lines BL1, BL2, and BL3, and the ground selection transistor GST may be connected to the common source line CSL.

Word lines (e.g., WL1) at the same height may be connected in common, the ground selection lines GSL1, GSL2, and GSL3 may be separated from each other, and the string selection lines SSL1, SSL2, and SSL3 may be separated from each other. An example in which the memory block BLKi is connected to eight gate lines GTL1, GTL2, . . . , GTL8 and three bit lines BL1, BL2, and BL3 is illustrated in FIG. 7, but an embodiment of the present disclosure is not limited thereto.

The bit density of the memory block BLKi may vary depending on the number of bits which each of the memory cells included in the memory block BLKi stores.

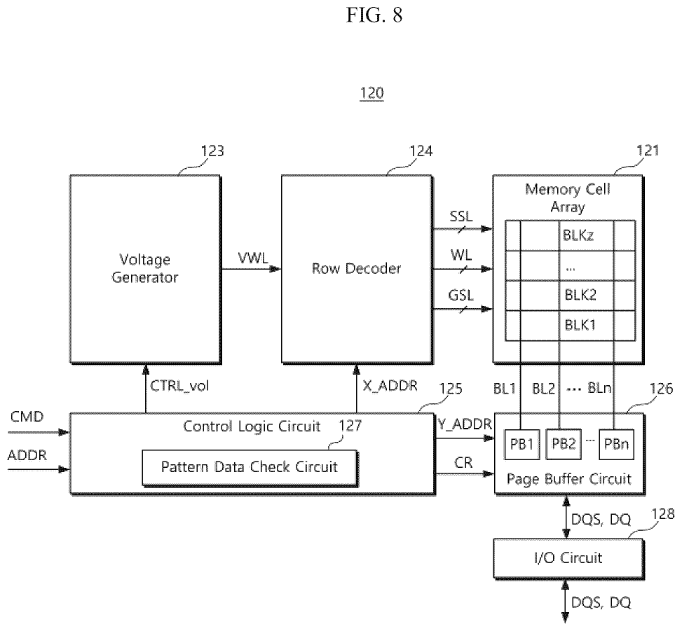

FIG. 8 is a diagram illustrating a configuration of a memory device according to an embodiment. The memory device 120 to be described with reference to FIG. 8 may correspond to the memory device 120 of FIG. 1.

Referring to FIG. 8, the memory device 120 may include the memory cell array 121, a voltage generator 123, a row decoder 124, the control logic circuit 125, the page buffer circuit 126, the pattern data check circuit 127, and an input/output (I/O) circuit 128.

The control logic circuit 125 may overall control various kinds of operations of the memory device 120. The control logic circuit 125 may output various kinds of control signals in response to the command CMD and/or the address ADDR from the memory interface circuit 118 (refer to FIG. 2). For example, the control signals may include a voltage control signal CTRL_vol, a row address X_ADDR, and a column address Y_ADDR.

The memory cell array 121 may include a plurality of memory blocks BLK1 to BLKz (z being a positive integer), and each of the plurality of memory blocks BLK1 to BLKz may include a plurality of memory cells. The memory blocks BLK1 to BLKz may be connected to the page buffer circuit 126 through bit lines BL1 to BLn and may be connected to the row decoder 124 through word lines WL, string selection lines SSL, and ground selection lines GSL.

The page buffer circuit 126 may include a plurality of page buffers PB1 to PBn (n being an integer of 3 or more), and the plurality of page buffers PB1 to PBn may be respectively connected to memory cells included in each of the plurality of memory blocks BLK1 to BLKz through the plurality of bit lines BL1 to BLn. Each of the plurality of page buffers PB1 to PBn may include a latch circuit. The latch circuit may include a plurality of latch circuits. The page buffer circuit 126 may select at least one of the bit line BL1 to BLn in response to the column address Y_ADDR. The page buffer circuit 126 may operate as a write driver or a sense amplifier depending on an operation mode.

For example, in the program operation, the page buffer circuit 126 may apply a bit line voltage corresponding to the data “DATA” to be programmed to a selected bit line.

In the read operation, the page buffer circuit 126 may sense a current or a voltage of the selected bit line to read data stored in a memory cell. The plurality of page buffers PB1 to PBn of the page buffer circuit 126 may sense data stored in memory cells through the plurality of bit lines BL1 to BLn and may temporarily store the sensed data as sensing data.

For example, the plurality of page buffers PB1 to PBn according to an embodiment may temporarily store data sensed from memory cells through the plurality of bit lines BL1 to BLn at a first time as the first sensing data.

The voltage generator 123 may generate various kinds of voltages for performing the program operation, the read operation, the erase operation, etc. based on the voltage control signal CTRL_vol.

In response to the row address X_ADDR, the row decoder 124 may select one of the plurality of word lines WL and may select one of the plurality of string selection lines SSL.

In an embodiment, the page buffer circuit 126 according to an embodiment may store the first pattern data PD_1 received from the memory controller 110 of FIG. 1 and the second pattern data PD_2 generated based on the seed. The page buffer circuit 126 may store the comparison result CR which is generated by the pattern data check circuit 127 as a result of comparing the first pattern data PD_1 and the second pattern data PD_2.

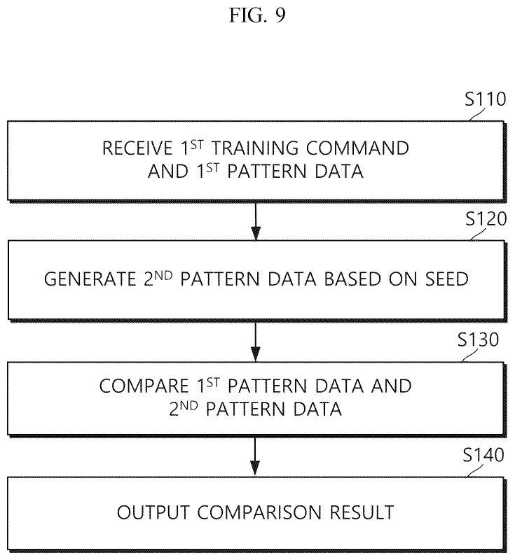

FIG. 9 is a flowchart describing an operation of a storage device according to an embodiment. Operations of FIG. 9 may be performed by the storage device 100 of FIG. 1. The description which is the same as or similar to the description of the embodiments given with reference to FIGS. 1 to 5 will be omitted for conciseness. An operation of the storage device 100 will be described with reference to FIGS. 1 and 9.

Referring to FIG. 9, in operation S110, the memory device 120 receives a first training command and first pattern data from the memory controller 110.

In an embodiment, the first training command may include the operation code 63h for performing write training of a transmission side or may include a new operation code. Depending on the operation code, the first training command may include an address or may not include an address.

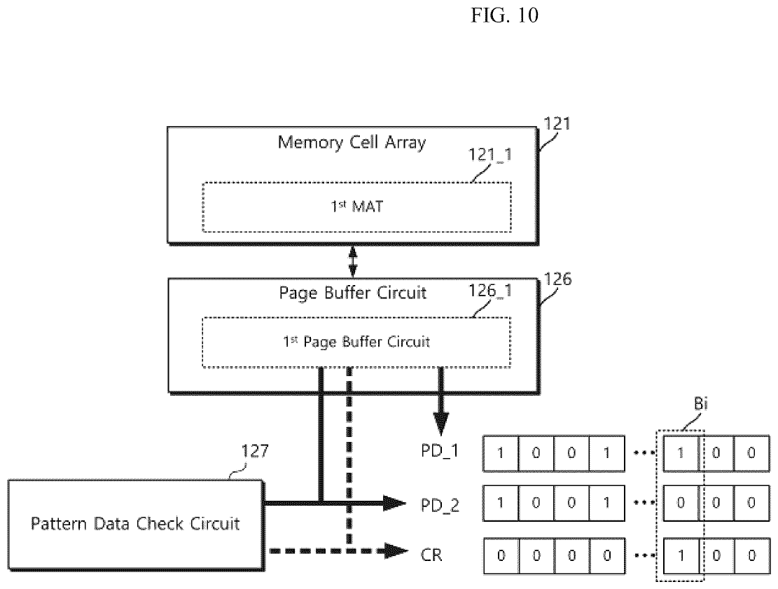

In an embodiment, the first training command may include the first pattern data. For example, the first pattern data may include a plurality of bits like the first pattern data PD_1 of FIG. 10.

Referring to FIG. 10, the memory device 120 may store the first pattern data PD_1 in a first page buffer circuit 126_1. The first page buffer circuit 126_1 may correspond to a first mat 121_1 of the memory cell array 121.

Returning to FIG. 9, in operation S120, the memory device 120 may generate second pattern data based on a seed in response to the first training command. For example, the second pattern data may include a plurality of bits like the second pattern data PD_2 of FIG. 10. The pattern data check circuit 127 of FIG. 5 may generate the second pattern data PD_2 based on the seed.

Referring to FIG. 10, the memory device 120 may store the second pattern data PD_2 in the first page buffer circuit 126_1. The second pattern data PD_2 may be stored in the first page buffer circuit 126_1 in which the first pattern data PD_1 are stored. That is, the first pattern data PD_1 and the second pattern data PD_2 may be used for the training operation of the same first mat 121_1 of the memory cell array 121.

Returning to FIG. 9, in operation S130, the memory device 120 may compare the first pattern data and the second pattern data. The memory device 120 may generate a first comparison result from comparing the first pattern data and the second pattern data.

Referring to FIG. 10, the memory device 120 may generate the comparison result CR by using a result of comparing the first pattern data PD_1 and the second pattern data PD_2 for each bit. In other words, the memory device 120 may perform a bit by bit comparison. For example, the memory device 120 may generate the comparison result CR by using a result of performing a bit by bit XOR operation on the first pattern data PD_1 and the second pattern data PD_2. Referring to FIG. 10, a value of a bit Bi of the first pattern data PD_1 is different from a value of a bit Bi of the second pattern data PD_2, which corresponds to the same bit position. Accordingly, a bit Bi of the comparison result, which corresponds to the same bit position, may have a bit value of “1” as a result of the XOR operation. The comparison result CR may have the same size of the first pattern data PD_1 and the second pattern data PD_2.

Returning to FIG. 9, in operation S140, the memory device 120 may output the comparison result. For example, the memory device 120 may output the comparison result CR of FIG. 10. As described above, in some embodiments, the memory device 120 may output comparison data (for example, a flag or other indication) indicating that at least one bit is different. The memory device 120 may output the comparison result as a response to the second training command of the memory controller 110.

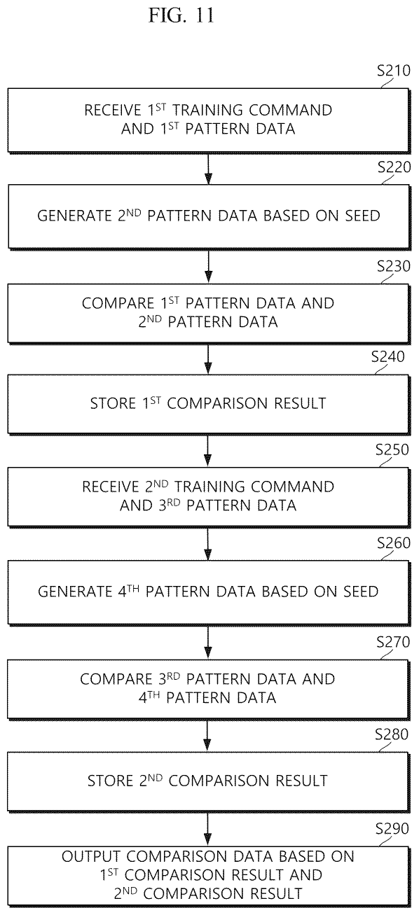

FIG. 11 is a flowchart describing an operation of a storage device according to an embodiment. Operations of FIG. 11 may be performed by the storage device 100 of FIG. 1. The description which is the same as or similar to the description of the embodiments given with reference to FIGS. 1 to 5, 9, and 10 will be omitted for conciseness. An operation of the storage device 100 will be described with reference to FIGS. 1 and 11.

Referring to FIG. 11, operation S210 to operation S230 are similar to operation S110 to operation S130 of FIG. 9. In operation S210, the memory device 120 receives a first training command and first pattern data from the memory controller 110. In operation S220, the memory device 120 generates second pattern data based on a seed. In operation S230, the memory device 120 compares the first pattern data and the second pattern data.

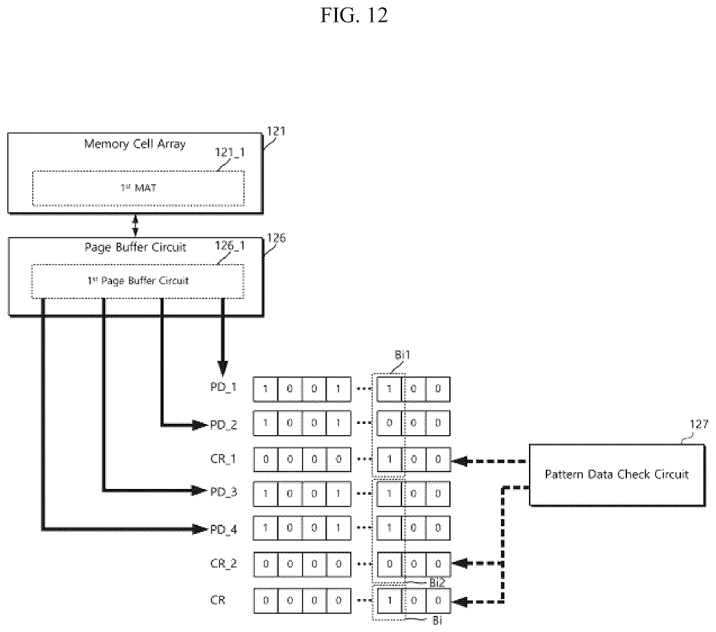

In operation S240, the memory device 120 stores a first comparison result obtained by comparing the first pattern data and the second pattern data, without outputting the first comparison result. For example, referring to FIG. 12, the memory device 120 stores a first comparison result CR_1 obtained by comparing the first pattern data PD_1 and the second pattern data PD_2 in the first page buffer circuit 126_1.

In operation S250, the memory device 120 receives a second training command and third pattern data from the memory controller 110. For example, the memory controller 110 may monitor the ready/busy signal R/B of the memory device 120, and after the ready/busy signal R/B transitions to the ready state, the memory controller 110 may transmit the second training command and the third pattern data to the memory device 120.

In operation S260, the memory device 120 may generate fourth pattern data based on a seed. For example, the pattern data check circuit 127 of FIG. 5 may generate the fourth pattern data by using the seed.

In operation S270, the memory device 120 compares the first pattern data and the second pattern data.

In operation S280, the memory device 120 stores a second comparison result obtained by comparing the third pattern data and the fourth pattern data. For example, referring to FIG. 12, the memory device 120 stores a second comparison result CR_2 obtained by comparing third pattern data PD_3 and fourth pattern data PD_4 in the first page buffer circuit 126_1.

In operation S290, the memory device 120 may output comparison data which are based on the first comparison result CR_1 and the second comparison result CR_2.

In an embodiment, the memory device 120 may continuously output the first comparison result CR_1 and the second comparison result CR_2.

In an embodiment, the memory device 120 may output comparison data obtained by performing an OR operation on the first comparison result CR_1 and the second comparison result CR_2. For example, referring to FIG. 12, the pattern data check circuit 127 may generate comparison data CR obtained by performing a bit by bit OR operation on the first comparison result CR_1 and the second comparison result CR_2. Referring to FIG. 12, a value of a first bit position Bi1 of the first comparison result CR_1 is different form a value of a second bit position Bi2 of the second comparison result CR_2. Accordingly, a value of a third bit position Bi of the comparison data CR may have “1”. The first bit position Bi1, the second bit position Bi2, and the third bit position Bi may be the same bit position.

According to the above description, the memory device 120 may determine whether the data strobe signal DQS for a page buffer circuit corresponding to the same mat is aligned, by using a plurality of pattern data plural times. Accordingly, the data signal DQ and/or the data strobe signal DQS may be accurately trained. Since a plurality of comparison results are simultaneously transmitted to the memory controller 110, a time taken to perform the training operation may be further reduced.

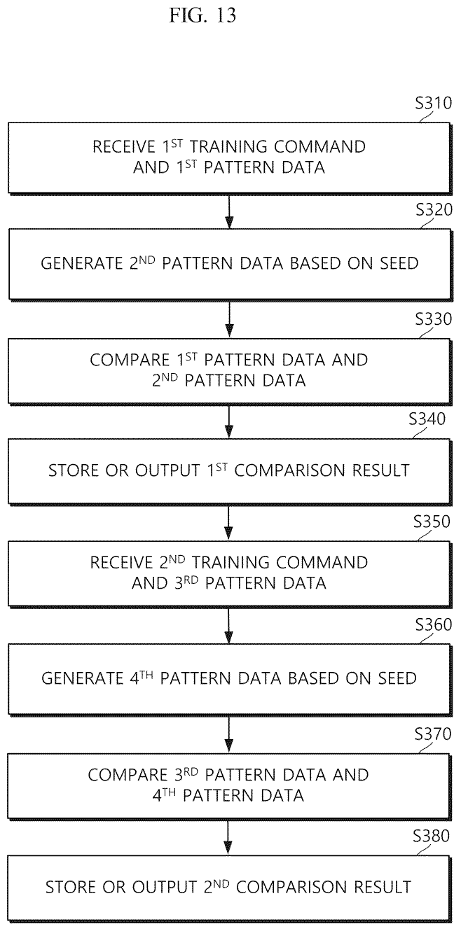

FIG. 13 is a flowchart describing an operation of a storage device according to an embodiment. Operations of FIG. 13 may be performed by the storage device 100 of FIG. 1. The description which is the same as or similar to the description of the embodiments given with reference to FIG. 11 will be omitted for conciseness. An operation of the storage device 100 according to an embodiment of FIG. 13 will be described based on a difference from the operation of FIG. 11.

Referring to FIG. 13, in operation S340, the first comparison result obtained by comparing the first pattern data received from the memory controller 110 of FIG. 1 with the second pattern data generated by the memory device 120 may be stored in the page buffer circuit 126 or may be directly output. Also, in operation S380, the second comparison result obtained by comparing the third pattern data received from the memory controller 110 of FIG. 1 with the fourth pattern data generated by the memory device 120 may be stored in the page buffer circuit 126 or may be directly output.

Times at which operation S310 to operation S340 are performed may be identical or similar to times at which operation S350 to operation S380 are performed. For example, operation S310 to operation S340 may be performed at the same times as operation S350 to operation S380 or may be performed in parallel with operation S350 to operation S380.

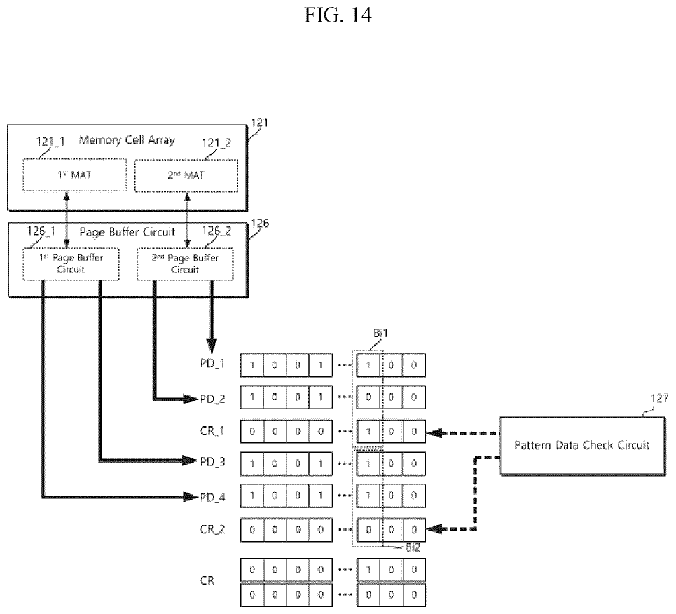

Referring to FIG. 14, the first pattern data PD_1, the second pattern data PD_2, and the first comparison result CR_1 may be stored in the first page buffer circuit 126_1 corresponding to the first mat 121_1. The third pattern data PD_3, the fourth pattern data PD_4, and the second comparison result CR_2 may be stored in a second page buffer circuit 126_2 corresponding to a second mat 121_2. Accordingly, the data strobe signals DQS for the page buffer circuits 126_1 and 126_2 corresponding to the different mats 121_1 and 121_2 may be respectively trained. The data strobe signals DQS for the page buffer circuits 126_1 and 126_2 may be respectively trained within a short time.

According to an embodiment, the first comparison result CR_1 in operation S340 may be output from the memory device 120 together with the second comparison result CR_2 in operation S380. In this case, unlike the comparison data CR of FIG. 12, the OR operation on the comparison data CR of FIG. 14 may not be performed, and the first comparison result CR_1 and the second comparison result CR_2 may be continuously output.

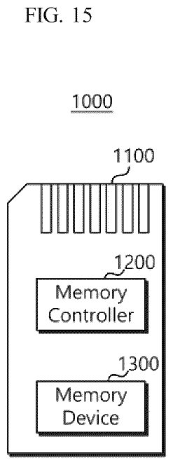

FIG. 15 is a block diagram illustrating an example of a configuration of a memory card system 1000 according to an embodiment. Referring to FIG. 15, the memory card system 100 may include a connector 1100, a memory controller 1200, and a memory device 1300. The memory controller 1200 and the memory device 1300 may corresponds respectively to the memory controller 110 and the memory device 120 described above with respect to FIGS. 1-14.

The memory controller 1200 may be electrically connected to the memory device 1300. The memory controller 1200 may be configured to access the memory device 1300 and to control the memory device 1300.

For example, the memory controller 1200 may control the read, write, and erase operations of the memory device 1300. In addition, the memory controller 1200 may control the memory device 1300 to perform the wear leveling, the garbage collection, etc. described with reference to FIG. 2.

The memory controller 1200 may be configured to provide an interface between the memory device 1300 and a host.

The memory controller 1200 may be configured to drive firmware for controlling the memory device 1300.

In an embodiment, the memory controller 1200 may include components such as a random access memory (RAM), a processor, a host interface, a memory interface, and an error correction circuit.

The memory controller 1200 may communicate with an external device through the connector 1100. For example, the memory controller 1200 may communicate with the host through the connector 1100.

The memory controller 1200 may communicate with the external device (e.g., the host) in compliance with a preset communication standard. For example, the memory controller 1200 may be configured to communicate with the external device through at least one of communication standards such as universal serial bus (USB), multimedia card (MMC), embedded MMC (eMMC), peripheral component interconnection (PCI), PCI-express (PCI-E), advanced technology attachment (ATA), serial-ATA, parallel-ATA, small computer small interface (SCSI), enhanced small disk interface (ESDI), integrated drive electronics (IDE), Firewire, universal flash storage (UFS), and/or nonvolatile memory express (NVMe).

The memory device 1300 may include any one of nonvolatile memory devices such as an electrically erasable and programmable ROM (EPROM), a NAND flash memory, a NOR flash memory, a phase-change RAM (PRAM), a resistive RAM (ReRAM), a ferroelectric RAM (FRAM), and a spin-torque magnetic RAM (STT-MRAM).

The memory card system 1000 may be integrated into a single semiconductor device to constitute a memory card. For example, the memory card system 1000 may be integrated into a single semiconductor device and may be implemented as a memory card such as a personal computer memory card international association (PCMCIA) card (PC card), a compact flash card (CF), a smart media (SM) card (SMC), a memory stick, a multimedia card (e.g., an MMC, an RS-MMC, an MMC micro, or an eMMC), an SD card (e.g., a miniSD card, a microSD card, or an SDHC), a universal flash memory (UFS), etc.

The memory device 1300 according to an embodiment may not output pattern data to the memory controller 1200, as described above with respect to FIGS. 1-14. The memory device 1300 may store received first pattern data in a page buffer circuit. The memory device 1300 may generate second pattern data based on a seed. The memory device 1300 may store the second pattern data in the page buffer circuit.

The memory device 1300 may compare the received first pattern data and the generated second pattern data. The memory device 1300 may output a comparison result. The output comparison result may be transmitted to the memory controller 1200. According to the above description with respect to FIGS. 1-14, the memory device 1300 may output the comparison result, which is obtained through the compare operation of the page buffer circuit without reading and writing pattern data from and in the memory cell array, and thus, a time taken to perform the training operation may decrease.

The memory controller 1200 may adjust a parameter associated with at least one of a data strobe signal and a data signal based on the comparison result.

Accordingly, a time taken for the memory card system 1000 to perform the data training operation may be reduced.

According to the present disclosure, a storage device and an operating method thereof may improve the performance of the storage device.

According to the present disclosure, a memory device may compare pattern data generated in the memory device with received pattern data without outputting the pattern data and may output a comparison result, and thus, the storage device and the operating method thereof may improve the performance of data training of the storage device.

While various embodiments have been described with reference to the drawings, it will be apparent to those of ordinary skill in the art that various changes and modifications may be made thereto without departing from the spirit and scope of the present disclosure as set forth in the following claims.

What is claimed is:

1. A storage device comprising:
a memory device including a plurality of nonvolatile memory cells; and
a memory controller configured to control the memory device,
wherein the memory device includes:
a memory cell array including the plurality of nonvolatile memory cells;
a control logic circuit configured to write or sense data in or from the memory cell array in response to a command received from the memory controller; and
a page buffer circuit configured to temporarily store sensing data sensed from the plurality of nonvolatile memory cells,
wherein the memory controller includes a training module configured to generate first pattern data based on a seed, and
wherein the control logic circuit includes a pattern data check circuit configured to:
generate second pattern data based on a first training command and the seed; and
compare the first pattern data and the second pattern data.

2. The storage device of claim 1, wherein the control logic circuit transmits a comparison result of the first pattern data and the second pattern data to the memory controller.

3. The storage device of claim 1, wherein the pattern data check circuit is configured to:
receive third pattern data from the memory controller in response to a second training command;
generate fourth pattern data based on the seed; and
compare the third pattern data and the fourth pattern data, and
wherein the control logic circuit simultaneously transmits a first comparison result obtained by comparing the first pattern data and the second pattern data and a second comparison result obtained by comparing the third pattern data and the fourth pattern data to the memory controller.

4. The storage device of claim 1, wherein the pattern data check circuit is configured to:
receive third pattern data from the memory controller in response to a second training command;
generate fourth pattern data based on the seed; and
compare the third pattern data and the fourth pattern data, and
wherein the control logic circuit performs an OR operation on a first comparison result obtained by comparing the first pattern data and the second pattern data and a second comparison result obtained by comparing the third pattern data and the fourth pattern data and transmits a result of the OR operation to the memory controller.

5. The storage device of claim 1, wherein the memory controller adjusts a parameter associated with at least one of a data strobe signal or a data signal, based on a result of comparing the first pattern data and the second pattern data.

6. The storage device of claim 1, wherein the control logic circuit transmits a result of comparing the first pattern data and the second pattern data to the memory controller in response to a second training command received from the memory controller.

7. The storage device of claim 1, wherein the pattern data check circuit includes:
a linear feedback shift register (LFSR) circuit configured to output the second pattern data based on the seed.

8. A memory device comprising:
a memory cell array including a plurality of nonvolatile memory cells;
a page buffer circuit configured to temporarily store sensing data sensed from the plurality of nonvolatile memory cells; and
a control logic circuit configured to write or sense data in or from the plurality of nonvolatile memory cells in response to a command received from an external device that is external to the memory device,
wherein the control logic circuit is configured to:
store each of a plurality of first pattern data in the page buffer circuit in response to a training command received from the external device;
generate a plurality of second pattern data based on a seed; and
output a result of comparing each of the plurality of first pattern data with a respective one of the plurality of second pattern data.

9. The memory device of claim 8, wherein the page buffer circuit includes a plurality of latch circuits,
wherein a first latch circuit among the plurality of latch circuits is configured to store the plurality of first pattern data, and
wherein a second latch circuit among the plurality of latch circuits is configured to store the plurality of second pattern data.

10. The memory device of claim 9, wherein a third latch circuit among the plurality of latch circuits is configured to store the result of the comparing.

11. A method of a storage device, the method comprising:
receiving, at a memory device, a first training command and first pattern data from a memory controller;
generating, at the memory device, second pattern data based on a seed, in response to the first training command;
generating, at the memory device, a first comparison result of comparing the first pattern data and the second pattern data; and
outputting, at the memory device, comparison data based on the first comparison result.

12. The method of claim 11, further comprising:
before the generating of the first comparison result, receiving, at the memory device, a second training command and third pattern data;
before the generating of the first comparison result, generating, at the memory device, fourth pattern data based on the seed, in response to the second training command;
before the generating of the first comparison result, generating, at the memory device, a second comparison result of comparing the third pattern data and the fourth pattern data; and
the outputting comprises outputting, at the memory device, the comparison data based on the first comparison result and the second comparison result.

13. The method of claim 12, further comprising:
storing, at the memory device, the first pattern data and the third pattern data in a page buffer circuit corresponding to different mats or to a same mat.

14. The method of claim 13, further comprising:
storing, at the memory device, the second pattern data and the fourth pattern data in a page buffer circuit corresponding to different mats or to a same mat.

15. The method of claim 12, further comprising:
storing the first comparison result and the second comparison result in page buffer circuits respectively corresponding to different mats.

16. The method of claim 15, wherein the comparison data include the first comparison result and the second comparison result.

17. The method of claim 11, further comprising:
outputting, at the memory device, the first comparison result,
receiving, at the memory controller, the first comparison result from the memory device; and
adjusting, at the memory controller, a parameter associated with at least one of a data strobe signal or a data signal based on the first comparison result.

18. The method of claim 11, further comprising:
outputting, at the memory device, the first comparison result,
receiving, at the memory controller, the first comparison result; and
adjusting, at the memory controller, a timing of a data strobe signal based on the first comparison result.

19. The method of claim 11, further comprising:
outputting, at the memory device, the first comparison result,
receiving, at the memory controller, the first comparison result; and
center-adjusting, at the memory controller, a data strobe signal to a data signal based on the first comparison result.

20. The method of claim 11, further comprising:
outputting, at the memory device, the first comparison result,
receiving, at the memory controller, the first comparison result; and
delaying, at the memory controller, a data strobe signal as much as a preset delay time, based on the first comparison result.
